(19) United States
(12) Patent Application Publication
(10) Pub. No.: US 2025/0283250 A1
(43) Pub. Date: Sep. 11, 2025

(54) METHOD FOR PRODUCING DOPED HALIDE PEROVSKITE SINGLE CRYSTAL

(71) Applicant: EWHA UNIVERSITY-INDUSTRY COLLABORATION FOUNDATION, Seoul (KR)

(72) Inventors: William JO, Seoul (KR); Sarah Su-O YOUN, Paju-si (KR)

(21) Appl. No.: 19/214,076

(22) Filed: May 21, 2025

Related U.S. Application Data
(63) Continuation of application No. PCT/KR2023/019077, filed on Nov. 24, 2023.

(30) Foreign Application Priority Data
Nov. 25, 2022 (KR) 10-2022-0160365
Aug. 22, 2023 (KR) 10-2023-0109797

(51) Int. Cl. C30B 29/12; C30B 7/14; C30B 29/66

(52) U.S. Cl. CPC C30B 29/12; C30B 7/14; C30B 29/66

(57) ABSTRACT

The present disclosure relates to a method of preparing a doped halide perovskite single crystal and a halide perovskite single crystal prepared by the method. A method of preparing a doped perovskite single crystal according to the present disclosure is capable of preparing a single crystal within about 24 hours by inverse temperature crystallization (ITC) and obtaining high-quality, large-area perovskite single crystals.

### CROSS-REFERENCE TO RELATED APPLICATION

This application is a continuation of PCT Application No. PCT/KR2023/019077, filed on Nov. 24, 2023, which claims priorities to Korean Patent Application Number 10-2022-0160365, filed on Nov. 25, 2022 and Korean Patent Application Number 10-2023-0109797, filed on Aug. 22, 2023, all of which are hereby incorporated by reference in their entirety.

### TECHNICAL FIELD

The present disclosure relates to a method of preparing a doped halide perovskite single crystal and a halide perovskite single crystal prepared by the method.

### BACKGROUND

Perovskite refers to a material with a structure of ABX₃. Herein, A contains a combination of monovalent cations such as organic methylammonium (MA⁺) or formamidinium (FA⁺) or inorganic cesium (Cs⁺); B contains metal cations such as Pb²⁺, Sn²⁺, Cu²⁺, Ge²⁺, Co²⁺, Ni²⁺, Fe²⁺, Mn²⁺, Yb²⁺, Eu²⁺, Cr²⁺, and Cd²⁺; and X contains halogen anions such as I⁻, Br⁻, and Cl⁻. Halide perovskite materials possess excellent photoresponsivity and thus have be applied to various devices such as solar cells, photodetectors, and X-ray detectors. By introducing dopants into the perovskite materials to fabricate n-type or p-type semiconductors, they can be further applied to a broader range of semiconductor devices (transistors). Perovskite single crystals exhibit excellent stability and thus demonstrate enhanced performance compared to thin films when applied to devices. However, there have been few attempts to apply n-type- or p-type-doped perovskite single crystals to various semiconductor devices. Also, the growth of single crystals is time-consuming and it is challenging to increase the crystal size.

### PRIOR ART DOCUMENT

### Patent Literature

Korean patent publication No. 10-2021-0018463

### DISCLOSURE OF THE INVENTION

### Problems to be Solved by the Invention

The present disclosure provides a method of preparing a doped halide perovskite single crystal and a halide perovskite single crystal prepared by the method.

However, problems to be solved by the present disclosure are not limited to the above-described problems. Although not described herein, other problems to be solved by the present disclosure can be clearly understood by a person with ordinary skill in the art from the following description.

### Means for Solving the Problems

A first aspect of the present disclosure provides a method of preparing a doped perovskite single crystal, including: dissolving compounds represented by the following Chemical Formulas 1, 2 and 3 in a solvent to prepare a precursor solution; and heating the precursor solution to grow a perovskite single crystal, wherein a molar ratio of the compounds represented by the Chemical Formulas 1, 2 and 3 is 1:1-n:n, and wherein the doped perovskite single crystal is a compound represented by the following Chemical Formula 4:

AX; [Chemical Formula 1]

M¹X₂; [Chemical Formula 2]

M₂X or M²X₃; [Chemical Formula 3]

A(M¹₁₋ₘM²ₘ)X₃; [Chemical Formula 4]

wherein, in the Chemical Formulas 1 to 4,

A includes at least one selected from organic ammonium, organic amidinium, Cs, Rb, and K; M¹ includes at least one divalent metal cation(s) selected from Pb, Cu, Ni, Co, Fe, Mn, Cr, Pd, Cd, Ca, Yb, Sn, Ge, Sr, Mg, Zn, and Eu; M² represents a dopant and includes at least one selected from a monovalent metal cation including Ag, Cu, Na, Li, or Ti and a trivalent metal cation including Bi, Sb, In, Au, Yb, Y, Ho, Er, Nd, Pr, Dy, La, or Eu; X includes at least one selected from Cl, Br, and I and is the same as or different from each other in the Chemical Formulas 1 to 4; and m represents a doping concentration of the dopant and is more than 0 to 0.2 or less.

A second aspect of the present disclosure provides a doped perovskite single crystal prepared by the method according to the first aspect, wherein the doped perovskite single crystal is represented by the Chemical Formula 4.

### Effects of the Invention

A method of preparing a doped perovskite single crystal according to embodiments of the present disclosure is capable of preparing a single crystal within about 24 hours by inverse temperature crystallization (ITC) and obtaining high-quality, large-area perovskite single crystals.

The method of preparing a doped perovskite single crystal according to embodiments of the present disclosure is capable of preparing high-crystallinity, large-area halide perovskite single crystals by adjusting a heating rate differently across temperature ranges depending on the type of halide perovskite and facilitating stable doping of dopants.

The method of preparing a doped perovskite single crystal according to embodiments of the present disclosure is capable of preparing n-type perovskite as well as p-type perovskite by expanding the type of dopants. Most conventional methyl ammonium (MA)-based halide perovskites exhibit p-type semiconductor characteristics and thus are limited in their application to semiconductor devices other than solar cells, photodetectors, and X-ray detectors. However, the perovskite single crystals obtained by the preparation method of the present disclosure are doped to become either p-type or n-type and thus can be applied to various semiconductor devices.

### BRIEF DESCRIPTION OF THE DRAWINGS

FIG. 1 is a schematic diagram illustrating a method of preparing a doped perovskite single crystal according to an example of the present disclosure.

FIG. 2 is a photograph of an MAPbBr₃ perovskite precursor solution depending on the concentration of bismuth (Bi) according to an example of the present disclosure.

FIG. 3 is a photograph of an MAPbBr₃ perovskite precursor solution depending on the concentration of silver (Ag) according to an example of the present disclosure.

FIG. 4 is a graph showing a heating rate depending on a temperature range when preparing doped MAPbBr₃ perovskite single crystals according to an example of the present disclosure.

FIGS. 5A to 5K are photographs of finally obtained doped MAPbBr₃ perovskite single crystals according to an example of the present disclosure.

FIG. 6 is a photograph of an MAPbI₃ perovskite precursor solution depending on the concentration of Bi according to an example of the present disclosure.

FIG. 7 is a graph showing a heating rate depending on a temperature range when preparing doped MAPbI₃ perovskite single crystals according to an example of the present disclosure.

FIGS. 8A to 8D are photographs of finally obtained doped MAPbI₃ perovskite single crystals according to an example of the present disclosure.

FIG. 9 is a graph showing the mol % ratio of Bi/(Bi+Pb) in the single crystals depending on the mol % ratio of Bi/(Bi+Pb) in the MAPbBr₃ perovskite precursor solution according to an example of the present disclosure.

FIGS. 10A(i) to 10F(vi) show scanning electron microscopy (SEM) and energy dispersive X-ray spectroscopy (EDX) images of Bi-doped MAPbBr₃ perovskite single crystals according to an example of the present disclosure.

FIG. 11A and FIG. 11B show X-ray diffraction (XRD) patterns (FIG. 11A) and rocking curve measurement results (FIG. 11B) of the Bi-doped MAPbBr₃ perovskite single crystals according to an example of the present disclosure.

FIG. 12A and FIG. 12B show XRD patterns (FIG. 12A) and lattice constants (FIG. 12B) of powder of the Bi-doped MAPbBr₃ perovskite single crystals according to an example of the present disclosure.

FIG. 13 shows Raman spectroscopy measurement results of the Bi-doped MAPbBr₃ perovskite single crystals according to an example of the present disclosure.

FIG. 14A to FIG. 14F show X-ray photoelectron spectroscopy (XPS) measurement results of the Bi-doped MAPbBr₃ perovskite single crystals according to an example of the present disclosure.

FIG. 15A to FIG. 15D show dark current-voltage (dark I-V) measurement results of the Bi-doped MAPbBr₃ perovskite single crystals according to an example of the present disclosure.

FIG. 16A and FIG. 16B show optical absorptance measurement results of the Bi-doped MAPbBr₃ perovskite single crystals according to an example of the present disclosure.

FIG. 17A and FIG. 17B show photoluminescence (PL) measurement results of the Bi-doped MAPbBr₃ perovskite single crystals according to an example of the present disclosure.

FIGS. 18A(i) to 18F(ii) show atomic force microscopy (AFM) measurement results of the Bi-doped MAPbBr₃ perovskite single crystals according to an example of the present disclosure.

FIG. 19 illustrates a work function of the Bi-doped MAPbBr₃ perovskite single crystals according to an example of the present disclosure.

### BEST MODE FOR CARRYING OUT THE INVENTION

Hereinafter, embodiments and examples of the present disclosure will be described in detail with reference to the accompanying drawings so that the present disclosure may be readily implemented by those skilled in the art. However, it is to be noted that the present disclosure is not limited to the embodiments and examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl” or “alkyl group” may individually include linear or branched alkyl groups having 1 to 12 carbon atoms, 1 to 10 carbon atoms, 1 to 8 carbon atoms, or 1 to 5 carbon atoms, and all the possible isomers thereof. For example, the alkyl or alkyl group may individually include methyl group (Me), ethyl group (Et), n-propyl group (ⁿPr), isopropyl group (ⁱPr), n-butyl group (ⁿBu), iso-butyl group (ⁱBu), tert-butyl group (^{t}Bu), sec-butyl group (^{s}Bu), n-pentyl group (ⁿPe), iso-pentyl group (ⁱPe), sec-pentyl group (^{s}Pe), tert-pentyl group (^{t}Pe), n-hexyl group, iso-hexyl group, heptyl group, 4,4-dimethyl pentyl group, octyl group, 2,2,4-trimethyl pentyl group, nonyl group, decyl group, undecyl group, dodecyl group, and isomers thereof, but may not be limited thereto.

In the following description, exemplary embodiments of the present disclosure will be described in detail, but the present disclosure may not be limited thereto.

A first aspect of the present disclosure provides a method of preparing a doped perovskite single crystal, including: dissolving compounds represented by the following Chemical Formulas 1, 2 and 3 in a solvent to prepare a precursor solution; and heating the precursor solution to grow a perovskite single crystal, wherein a molar ratio of the compounds represented by the Chemical Formulas 1, 2 and 3 is 1:1-n:n, and wherein the doped perovskite single crystal is a compound represented by the following Chemical Formula 4:

AX; [Chemical Formula 1]

M¹X₂; [Chemical Formula 2]

M²X or M²X₃; [Chemical Formula 3]

A(M¹₁₋ₘM²ₘ)X₃; [Chemical Formula 4]

wherein, in the Chemical Formulas 1 to 4, A includes at least one selected from organic ammonium, organic amidinium, Cs, Rb, and K; M¹ includes at least one divalent metal cation(s) selected from Pb, Cu, Ni, Co, Fe, Mn, Cr, Pd, Cd, Ca, Yb, Sn, Ge, Sr, Mg, Zn, and Eu; M² represents a dopant and includes at least one selected from a monovalent metal cation including Ag, Cu, Na, Li, or Ti and a trivalent metal cation including Bi, Sb, In, Au, Yb, Y, Ho, Er, Nd, Pr, Dy, La, or Eu; X includes at least one selected from Cl, Br, and I and is the same as or different from each other in the Chemical Formulas 1 to 4; and m represents a doping concentration of the dopant and is more than 0 to 0.2 or less.

In an embodiment of the present disclosure, the organic ammonium may include at least one selected from alkylammonium containing an alkyl group having 1 to 15 carbon atoms (for example, methylammonium, ethylammonium, propylammonium, butylammonium, pentylammonium, hexylammonium, heptylammonium, octylammonium, nonylammonium, decylammonium, undecylammonium, dodecylammonium, and their possible isomers), methylenediammonium, dimethylammonium, phenethylammonium, 4-fluoro-phenethylammonium, pyrenyl ammonium, pyrenyl methylammonium, and pyrenyl ethylammonium, but may not be limited thereto.

In an embodiment of the present disclosure, the organic amidinium may include at least one selected from formamidinium, acetamidinium, and guanidinium.

In an embodiment of the present disclosure, in the Chemical Formulas 1 to 4, A may include at least one selected from alkylammonium containing an alkyl group having 1 to 15 carbon atoms, methylenediammonium, dimethylammonium, phenethylammonium, 4-fluoro-phenethylammonium, pyrene-ammonium, pyrene-methylammonium, pyrene-ethylammonium, formamidinium, acetamidinium, guanidinium, Cs, Rb, and K.

In an embodiment of the present disclosure, X is a halogen selected from Cl, Br, or I, and the perovskite may be halide perovskite.

In an embodiment of the present disclosure, M² in the Chemical Formula 3 may be a dopant. In an embodiment of the present disclosure, the doped perovskite single crystal may be a perovskite single crystal doped with M².

In an embodiment of the present disclosure, when M² is a trivalent metal cation including Bi, Sb, In, Au, Yb, Y, Ho, Er, Nd, Pr, Dy, La, or Eu, the doped perovskite single crystal may be an n-type semiconductor compound.

In an embodiment of the present disclosure, when M² is a monovalent metal cation including Ag, Cu, Na, Li, or Ti, the doped perovskite single crystal may be a p-type semiconductor compound.

In an embodiment of the present disclosure, n may be more than 0 to 0.5 or less, but may not be limited thereto. In an embodiment of the present disclosure, n may be more than 0 to 0.5 or less, about 0.01 to about 0.5, about 0.01 to about 0.4, about 0.01 to about 0.3, about 0.01 to about 0.2, about 0.01 to about 0.15, about 0.01 to about 0.1, about 0.02 to about 0.5, about 0.02 to about 0.4, about 0.02 to about 0.3, about 0.02 to about 0.2, about 0.02 to about 0.15, about 0.02 to about 0.1, about 0.05 to about 0.5, about 0.05 to about 0.4, about 0.05 to about 0.3, about 0.05 to about 0.2, about 0.05 to about 0.15, or about 0.05 to about 0.1, but may not be limited thereto.

In an embodiment of the present disclosure, m may represent a doping concentration of the dopant in the perovskite single crystal. In an embodiment of the present disclosure, m may represent M²/(M¹+M²) mol % in the perovskite single crystal.

In an embodiment of the present disclosure, m may increase in proportion to n. In an embodiment of the present disclosure, m may increase in proportion to a molar ratio of M² (n) in the precursor solution.

In an embodiment of the present disclosure, m may be more than 0 to 0.2 or less, more than 0 to 0.1 or less, more than 0 to 0.01 or less, about 0.00001 to about 0.2, about 0.00001 to about 0.1, about 0.00001 to about 0.01, about 0.00001 to about 0.005, about 0.00001 to about 0.004, about 0.00001 to about 0.003, about 0.00001 to about 0.002, about 0.00001 to about 0.001, about 0.0001 to about 0.2, about 0.0001 to about 0.1, about 0.0001 to about 0.01, about 0.0001 to about 0.005, about 0.0001 to about 0.004, about 0.0001 to about 0.003, about 0.0001 to about 0.002, about 0.0001 to about 0.001, about 0.001 to about 0.2, about 0.001 to about 0.1, about 0.001 to about 0.01, about 0.001 to about 0.005, about 0.001 to about 0.004, about 0.001 to about 0.003, or about 0.001 to about 0.002, but may not be limited thereto.

In an embodiment of the present disclosure, a molar concentration of the precursor solution is about 0.5 M to about 3 M, but may not be limited thereto. In an embodiment of the present disclosure, a molar concentration of the precursor solution is about 0.5 M to about 3 M, about 0.5 M to about 2 M, about 0.5 M to about 1.7 M, about 0.5 M to about 1.5 M, about 0.5 M to about 1.3 M, about 0.5 M to about 1.2 M, about 0.5 M to about 1 M, about 0.7 M to about 3 M, about 0.7 M to about 2 M, about 0.7 M to about 1.7 M, about 0.7 M to about 1.5 M, about 0.7 M to about 1.3 M, about 0.7 M to about 1.2 M, about 0.7 M to about 1 M, about 0.9 M to about 3 M, about 0.9 M to about 2 M, about 0.9 M to about 1.7 M, about 0.9 M to about 1.5 M, about 0.9 M to about 1.3 M, about 0.9 M to about 1.2 M, or about 0.9 M to about 1 M, but may not be limited thereto.

In an embodiment of the present disclosure, in the Chemical Formula 4, A may include at least one selected from methyl ammonium (MA), formamidinium (FA), and Cs; M¹ may be Pb; and X may include at least one selected from Cl, Br, and I.

In an embodiment of the present disclosure, the perovskite may include at least one selected from MAPbCl₃, MAPbBr₃, MAPbI₃, FAPbCl₃, FAPbBr₃, FAPbI₃, CsPbBr3, and CsPbI₃, but may not be limited thereto.

In an embodiment of the present disclosure, the solvent may be a protonic polar solvent capable of dissolving the perovskite precursor compound. In an embodiment of the present disclosure, the solvent may include at least one selected from dimethylformamide (DMF), dimethyl sulfoxide (DMSO), gamma butyrolactone (GBL), acetonitrile, N-methylpyrrolidone (NMP), isopropyl alcohol (IPA), dichlorobenzene (DCB), and toluene, but may not be limited thereto.

In an embodiment of the present disclosure, the doped perovskite single crystal may be MAPbBr₃ or MAPbI₃ doped by the dopant.

In an embodiment of the present disclosure, the doped perovskite single crystal may be MAPbBr₃ or MAPbI₃ doped by the dopant of Bi or Ag.

In an embodiment of the present disclosure, the perovskite single crystal may be grown by inverse temperature crystallization (ITC), which enables the perovskite single crystal to be obtained within about 24 hours.

In an embodiment of the present disclosure, when the precursor solution is heated, a heating rate may vary depending on a temperature range.

In an embodiment of the present disclosure, when the precursor solution is heated, the heating rate may decrease as a temperature in the temperature range increases. In general, halide perovskite single crystals have been grown at a constant heating rate, which poses a challenge in preparing high-crystallinity, large-area single crystals. According to the present disclosure, when the precursor solution is heated, it is possible to prepare high-crystallinity, large-area halide perovskite single crystals by adjusting a heating rate differently across temperature ranges. In particular, by adjusting the heating rate differently across the temperature ranges depending on the type of halide perovskite, it is possible to prepare high-crystallinity, large-area perovskite single crystals and facilitate stable doping of dopants.

In an embodiment of the present disclosure, when the perovskite is MAPbBr₃, the heating rate may be about 0.2° C./min to about 0.3° C./min in a temperature range of about 20° C. to about 60° C., about 0.1° C./min to about 0.2° C./min in a temperature range of about 60° C. to about 100° C., about 0.01° C./min to about 0.1° C./min in a temperature range of about 100° C. to about 130° C., and about 0.01° C./min to about 0.1° C./min in a temperature range of about 130° C. to about 150° C.

In an embodiment of the present disclosure, when the perovskite is MAPbI₃, the heating rate may be about 0.01° C./min to about 0.1° C./min in a temperature range of about 80° C. to about 110° C., about 0.01° C./min to about 0.1° C./min in a temperature range of about 110° C. to about 140° C., and about 0.01° C./min to about 0.1° C./min in a temperature range of about 140° C. to about 170° C.

In an embodiment of the present disclosure, when the perovskite is MAPbI₃, the heating rate may be about 0.05° C./min to about 0.1° C./min in a temperature range of about 80° C. to about 110° C., about 0.03° C./min to about 0.05° C./min in a temperature range of about 110° C. to about 140° C., and about 0.01° C./min to about 0.03° C./min in a temperature range of about 140° C. to about 170° C.

In an embodiment of the present disclosure, when the perovskite is MAPbBr₃, a single crystal with a size of about 7 mm×7 mm can be prepared within about 24 hours by the above-described method.

In an embodiment of the present disclosure, when the perovskite is MAPbI₃, a single crystal with a size of about 2 cm×2 cm can be prepared within about 24 hours by the above-described method.

In an embodiment of the present disclosure, the precursor solution may further include formic acid.

In an embodiment of the present disclosure, when the perovskite is MAPbI₃, the precursor solution includes formic acid, and thus, the crystallinity of the perovskite single crystal can be improved.

A second aspect of the present disclosure provides a doped perovskite single crystal prepared by the method according to the first aspect, wherein the doped perovskite single crystal is represented by the following Chemical Formula 4:

A(M¹₁₋ₘM²ₘ)X₃; [Chemical Formula 4]

wherein, in the Chemical Formulas 1 to 4,

A includes at least one selected from organic ammonium, organic amidinium, Cs, Rb, and K; M¹ includes at least one divalent metal cation(s) selected from Pb, Cu, Ni, Co, Fe, Mn, Cr, Pd, Cd, Ca, Yb, Sn, Ge, Sr, Mg, Zn, and Eu; M² represents a dopant and includes at least one selected from a monovalent metal cation including Ag, Cu, Na, Li, or Ti and a trivalent metal cation including Bi, Sb, In, Au, Yb, Y, Ho, Er, Nd, Pr, Dy, La, or Eu; X includes at least one selected from Cl, Br, and I and is the same as or different from each other in the Chemical Formulas 1 to 4; and m represents a doping concentration of the dopant and is more than 0 to 0.2 or less.

Detailed descriptions of parts of the second aspect, which overlap with those of the first aspect, are omitted hereinafter, but the descriptions of the first aspect of the present disclosure may be identically applied to the second aspect of the present disclosure, even though they are omitted hereinafter.

In an embodiment of the present disclosure, m represents a doping concentration of the dopant in the perovskite single crystal.

In an embodiment of the present disclosure, m may be more than 0 to about 0.2 or less, more than 0 to about 0.1 or less, more than 0 to about 0.01 or less, about 0.00001 to about 0.2, about 0.00001 to about 0.1, about 0.00001 to about 0.01, about 0.00001 to about 0.005, about 0.00001 to about 0.004, about 0.00001 to about 0.003, about 0.00001 to about 0.002, about 0.00001 to about 0.001, about 0.0001 to about 0.2, about 0.0001 to about 0.1, about 0.0001 to about 0.01, about 0.0001 to about 0.005, about 0.0001 to about 0.004, about 0.0001 to about 0.003, about 0.0001 to about 0.002, about 0.0001 to about 0.001, about 0.001 to about 0.2, about 0.001 to about 0.1, about 0.001 to about 0.01, about 0.001 to about 0.005, about 0.001 to about 0.004, about 0.001 to about 0.003, or about 0.001 to about 0.002, but may not be limited thereto.

In an embodiment of the present disclosure, when M² is a trivalent metal cation including Bi, Sb, In, Au, Yb, Y, Ho, Er, Nd, Pr, Dy, La, or Eu, the doped perovskite single crystal may be an n-type semiconductor compound.

In an embodiment of the present disclosure, when M² is a monovalent metal cation including Ag, Cu, Na, Li, or Ti, the doped perovskite single crystal may be a p-type semiconductor compound.

In an embodiment of the present disclosure, a full width at half maximum (FWHM) of XRD peak of the doped perovskite single crystal may be about 0.07 or less, about 0.067 or less, or about 0.0665 or less. In an embodiment of the present disclosure, the doped perovskite single crystal compared to doped perovskite single crystals prepared by conventional doping methods can maintain high crystallinity while exhibiting an improved doping concentration.

In an embodiment of the present disclosure, the doped perovskite single crystal can maintain its bonding structure despite the doping.

In an embodiment of the present disclosure, a conductivity of the doped perovskite single crystal may be about 8×10⁻⁸ Ω⁻¹cm⁻¹ or more, about 3×10⁻⁸ Ω⁻¹cm⁻¹ or more, about 5×10⁻⁸ Ω⁻¹cm⁻¹ or more, about 8×10⁻⁸ Ω⁻¹cm⁻¹ or more, about 1×10⁻⁷ Ω⁻¹cm⁻¹ or more, or about 3×10⁻⁷ Ω⁻¹cm⁻¹ or more.

In an embodiment of the present disclosure, a carrier lifetime (τ) of the doped perovskite single crystal may be about 500 ns or more, about 600 ns or more, about 650 ns or more, about 680 ns or more.

In an embodiment of the present disclosure, the doped perovskite single crystal may be applied to solar cells, photodetectors, X-ray detectors, or transistors.

### MODE FOR CARRYING OUT THE INVENTION

Hereinafter, example embodiments are described in more detail by using Examples, but the present disclosure may not limited to the Examples.

### EXAMPLES

### Example 1: Preparation of Perovskite (Bi- or Ag-Doped Methylammonium Lead Bromide (MAPbBr₃)) Single Crystal (FIG. 1)

### 1) Preparation of Perovskite Precursor Solution

Methylammonium bromide (MABr); lead (II) bromide (PbBr₂); and either bismuth (III) bromide (BiBr₃) or silver bromide (AgBr) were mixed in a molar ratio of 1:1-n:n, and 1 M of the mixture was dissolved in 4 mL of N, N-dimethyl formamide (DMF) to prepare a precursor solution.

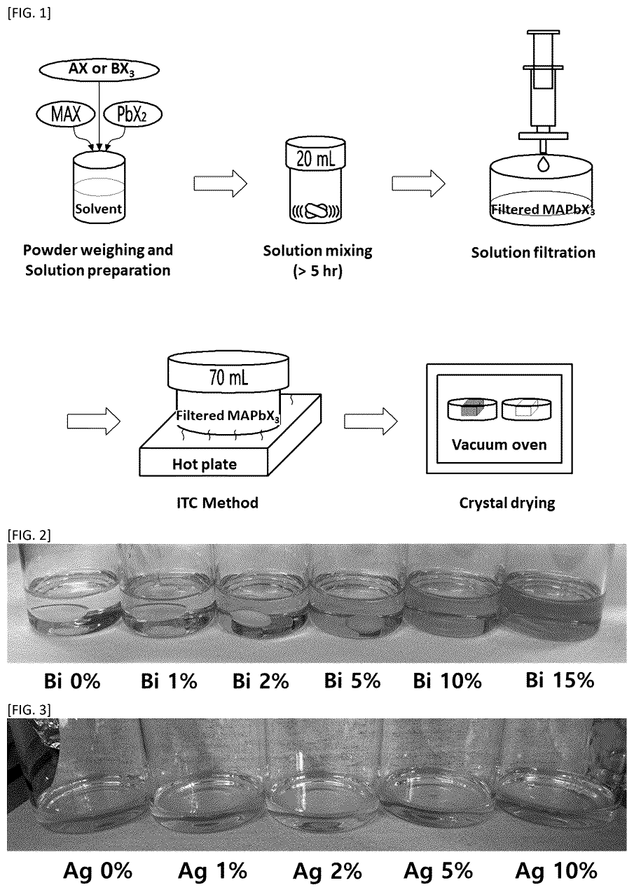

The precursor solution was filtered through a 0.2 μm filter to remove the undissolved compound. FIG. 2 is a photograph of the filtered precursor solution depending on a concentration (n) of bismuth (Bi) (0%, 1%, 2%, 5%, 10%, and 15%), and FIG. 3 is a photograph of the filtered precursor solution depending on a concentration (n) of silver (Ag) (0%, 1%, 2%, 5%, and 10%).

### 2) Growth of Perovskite Single Crystal

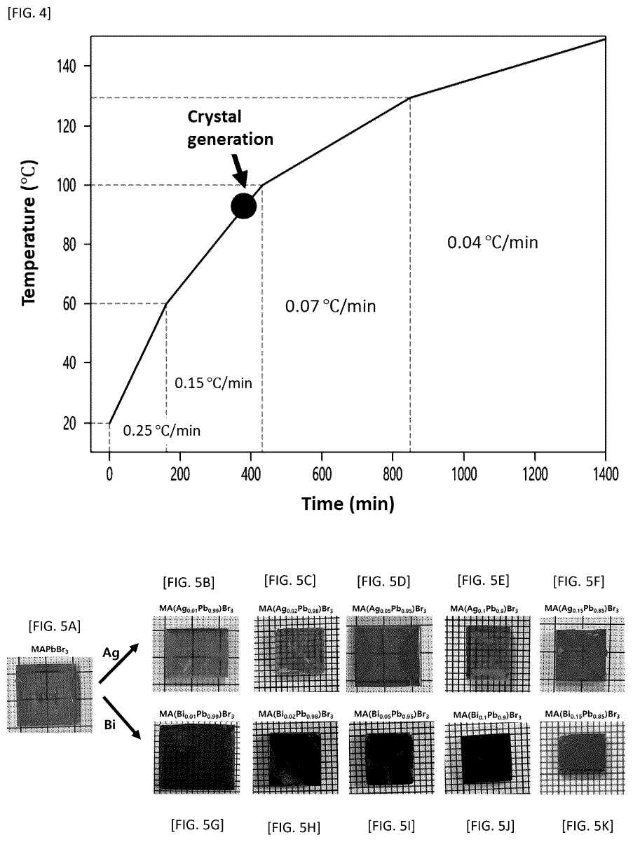

As shown in FIG. 4, the temperature of the filtered solution was increased by using a hot plate while adjusting a heating rate, and the perovskite was crystallized and grown simultaneously by inverse temperature crystallization (ITC). The heating rate was 0.25° C./min in a temperature range of 20° C. to 60° C., 0.15° C./min in a temperature range of 60° C. to 100° C., 0.07° C./min in a temperature range of 100° C. to 130° C., and 0.04° C./min in a temperature range of 130° C. to 150° C. The obtained perovskite crystal became visible to the naked eye at a temperature range of 90° C. to 100° C.

### 3) Drying of Single Crystal

The obtained halide perovskite single crystal was dried in a vacuum oven at 80° C. for 3 hours. FIGS. 5A to 5K are photographs of finally obtained single crystals.

### Example 2: Preparation of Perovskite (Bi-Doped Methylammonium Lead Iodide (MAPbI₃)) Single Crystal

### 1) Preparation of Perovskite Precursor Solution

Methylammonium iodide (MAI); lead(II) iodide (PbI₂); and bismuth (III) iodide (BiI₃) were mixed in a molar ratio of 1:1-n:n, and 1.2 M of the mixture was dissolved in 4 mL of gamma-butyrolactone (GBL) to prepare a precursor solution.

After the precursor solution was thoroughly stirred at 60° C. for 5 hours, formic acid (HCOOH) corresponding to 2% of the precursor solution volume was added, and the mixture was dissolved for additional 30 minutes.

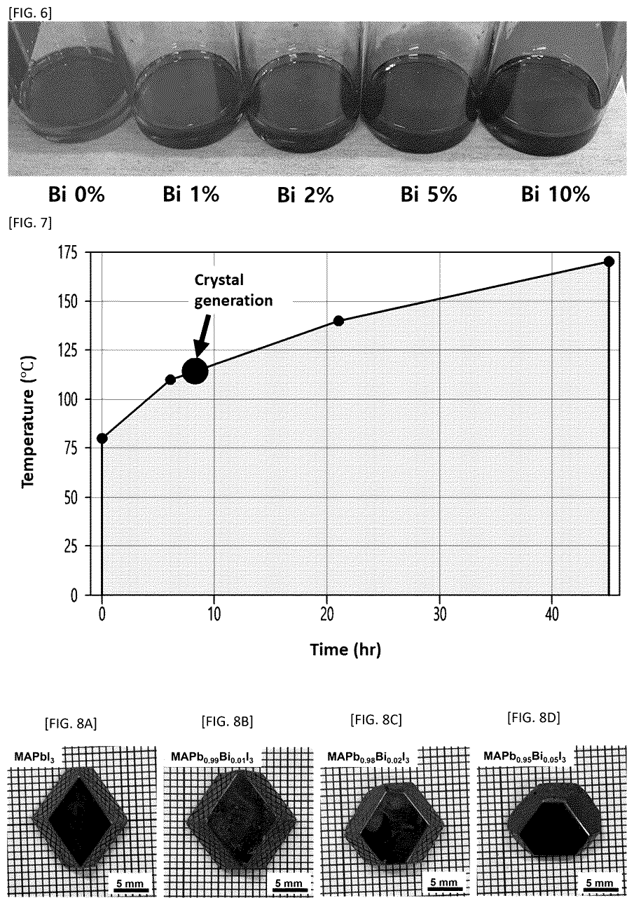

The precursor solution was filtered through a 0.2 μm filter to remove the undissolved compound. FIG. 6 is a photograph of the filtered precursor solution depending on a concentration (n) of Bi (0%, 1%, 2%, 5%, and 10%).

### 2) Growth of Perovskite Single Crystal

As shown in FIG. 7, the temperature of the filtered solution was increased by using a hot plate while adjusting a heating rate, and the perovskite was crystallized and grown simultaneously by inverse temperature crystallization. The heating rate of the solution was 0.083° C./min in a temperature range of 80° C. to 110° C., 0.033° C./min in a temperature range of 110° C. to 140° C., and 0.021° C./min in a range temperature of 140° C. to 170° C. The obtained perovskite crystal became visible to the naked eye at a temperature range of 110° C. to 123° C.

### 3) Drying of Single Crystal

The obtained halide perovskite single crystal was dried in a vacuum oven at 80° C. for 3 hours. FIGS. 8A to 8D are photographs of finally obtained single crystals.

### TEST EXAMPLE

### Test Example 1: Evaluation of Bi-Doped MAPbBr₃

### Inductively Coupled Plasma Optical Emission Spectrometry (ICP-OES)

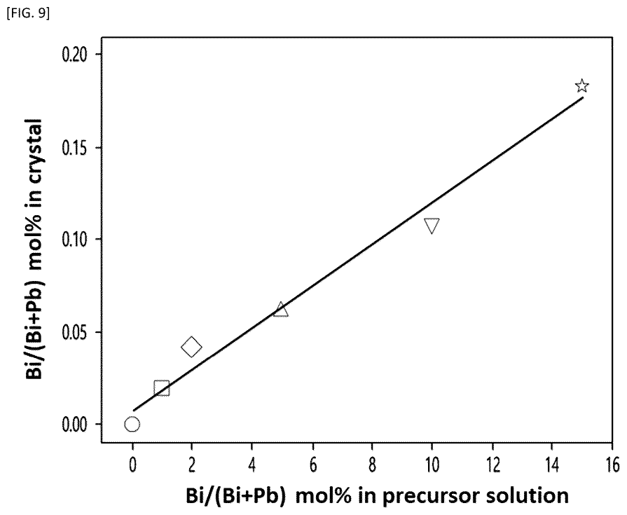

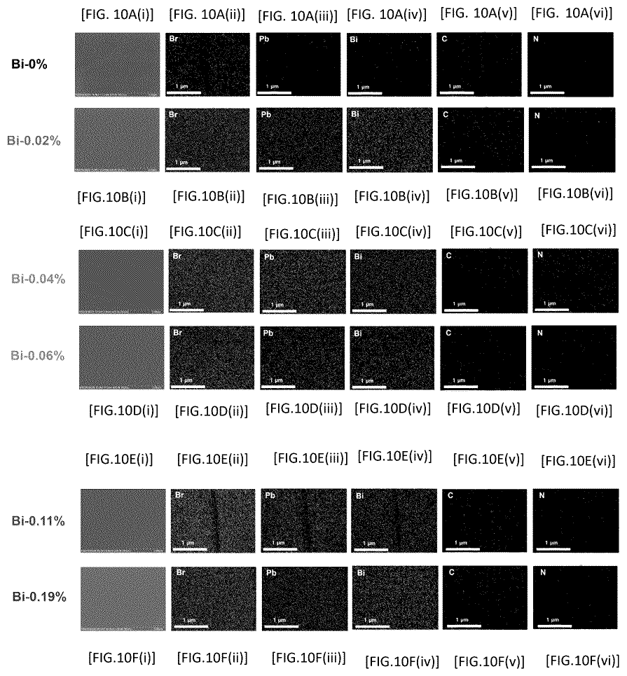

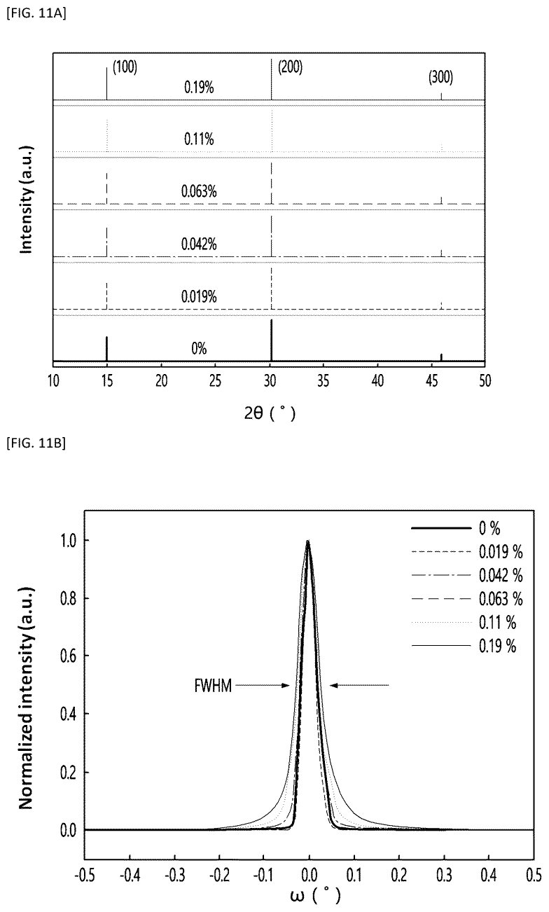

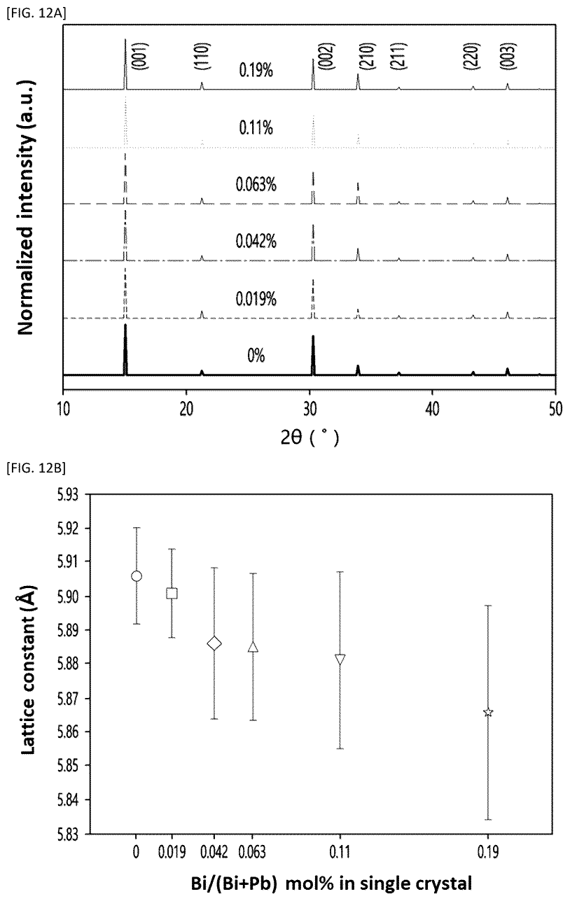

A bismuth (Bi) content in the Bi-doped MAPbBr₃ single crystal prepared in Example 1 was measured by inductively coupled plasma optical emission spectrometry (ICP-OES). FIG. 9 is a graph showing the mol % ratio of Bi/(Bi+Pb) in the single crystal, as measured by ICP-OES, depending on the mol % ratio of Bi/(Bi+Pb) in the precursor solution. The amount of Bi contained in the single crystal increased linearly in proportion to the amount of Bi added to the precursor solution. The values in FIG. 9 are shown in Table 1 below. When the concentration of Bi added to the solution was 0%, 1%, 2%, 5%, 10%, or 15%, the concentration of Bi contained in the single crystal was 0%, 0.02%, 0.04%, 0.06%, 0.11%, or 0.19%, respectively, which confirms the successful incorporation of Bi. Hereinafter, the names of the respective samples are denoted by the actual concentrations of Bi contained in the single crystal.

TABLE 1

| Concentration of | | | Bi/(Bi + Pb) (mol %) |
|---|---|---|---|
| Bi(mol %) in the | | | in the perovskite |
| precursor solution | Bi wt % | Pb wt % | single crystal |
| 0 | — | 47.421 ± 0.69 | 0 |
| 1 | 0.009 ± 2.21 | 45.613 ± 0.80 | 0.019 |
| 2 | 0.032 ± 2.78 | 74.884 ± 0.61 | 0.042 |
| 5 | 0.032 ± 3.03 | 49.960 ± 0.79 | 0.063 |
| 10 | 0.051 ± 0.88 | 46.276 ± 0.49 | 0.11 |
| 15 | 0.102 ± 0.65 | 54.983 ± 0.73 | 0.19 |

### Scanning Electron Microscopy (SEM) and Energy Dispersive X-Ray Spectroscopy (EDX)

FIGS. 10A(i) to 10F(vi) show SEM and EDX images of the single crystals. The SEM images confirmed the absence of grain boundaries in the single crystal, and the SEM-EDX analysis revealed that Bi was uniformly distributed in the single crystal. It can be seen that the incorporation of Bi does not change the internal structure of the single crystal and Bi is well located in the structure of MAPbBr₃.

### X-Ray Diffraction (XRD)

X-ray diffraction (XRD) analysis was conducted to investigate structural changes in the Bi-doped MAPbBr₃ single crystal. Referring to FIG. 11A, the XRD patterns corresponding to different concentrations of Bi in the single crystal exhibited only peaks associated with the (100), (200), and (300) planes, with no shift in peak positions. This confirms a single-phase perovskite structure (FIG. 11B). Referring to FIG. 11B and Table 2 below, a full width at half maximum (FWHM) of X-ray rocking curves showed a slight increase in proportion to a doping concentration of Bi. However, the FWHM remained below 0.0665 at all doping concentrations of Bi, which indicates high crystallinity.

TABLE 2

| Bi Concentraiton (mol %) | FWHM |
|---|---|
| 0 | 0.0445 |
| 0.019 | 0.0394 |
| 0.042 | 0.0424 |
| 0.063 | 0.0492 |
| 0.11 | 0.0570 |
| 0.19 | 0.0665 |

Further, XRD measurements were performed in the form of powder (FIG. 12A and FIG. 12B). Referring to FIG. 12A, peaks corresponding to the perovskite structure appeared at all concentrations of Bi, and calculated lattice parameters tended to decrease as the concentrations increased. This is presumed to be due to lattice distortion caused by differences in bonding strength of Bi in the single crystal.

### Raman Spectroscopy

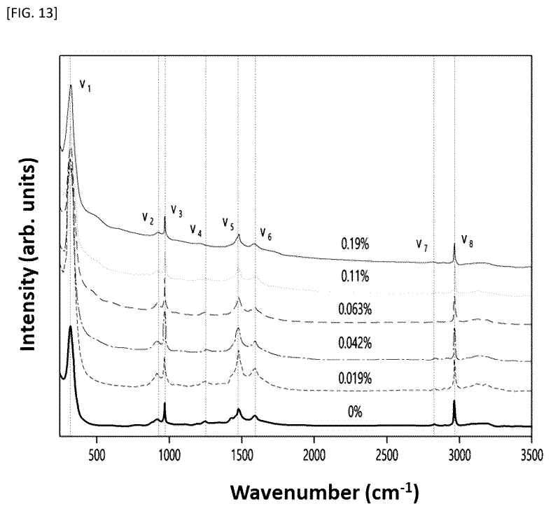

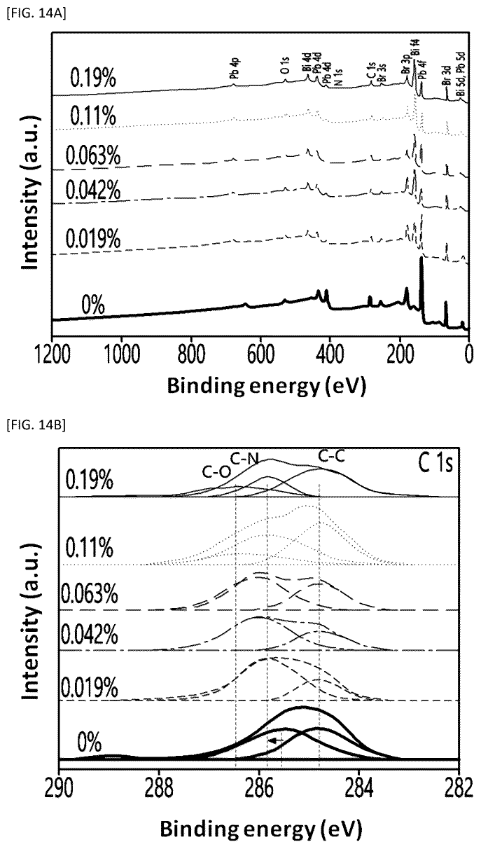

Structural changes in the single crystal caused by Bi doping were examined by Raman spectroscopy (FIG. 13). As in the XRD results, no new peaks appeared and no existing peaks disappeared, which indicates that the bonding structure of the perovskite single crystal remained unchanged even after Bi doping. Table 3 below shows the positions of the Raman peaks and their corresponding vibrational modes.

TABLE 3

| Peak | Position (cm⁻¹) | Vibrational modes |
|---|---|---|
| ν₁ | 324 | C—N torsion |
| ν₂ | 919 | MA rocking |
| ν₃ | 969 | C—N stretching |
| ν₄ | 1248 | CH₃NH₃ rocking |
| ν₅ | 1478 | NH₃ symmetric bending |
| ν₆ | 1587 | NH₃ asymmetric bending |
| ν₇ | 2828 | NH₃ stretching |
| ν₈ | 2967 | CH₃ asymmetric stretching |

### X-Ray Photoelectron Spectroscopy (XPS)

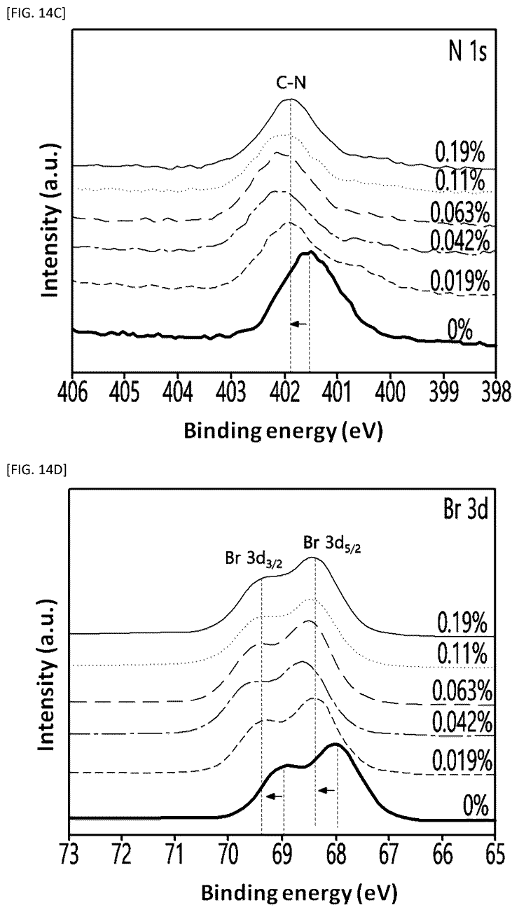

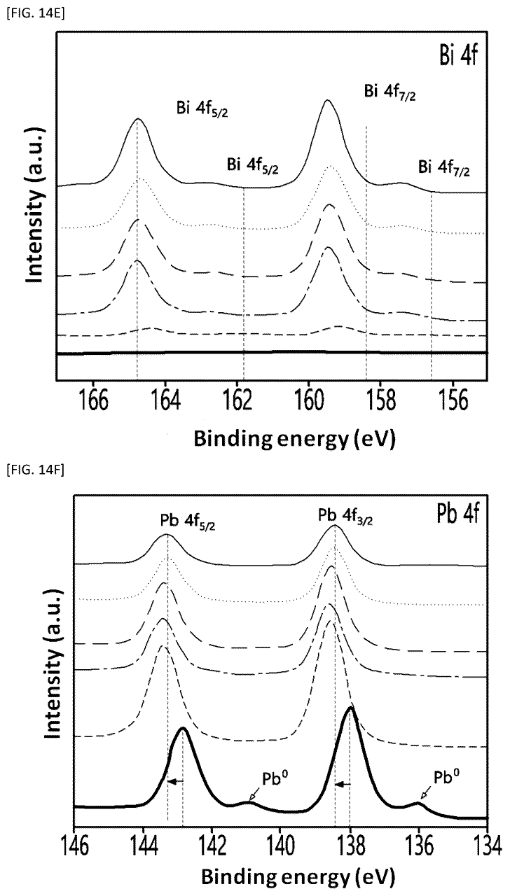

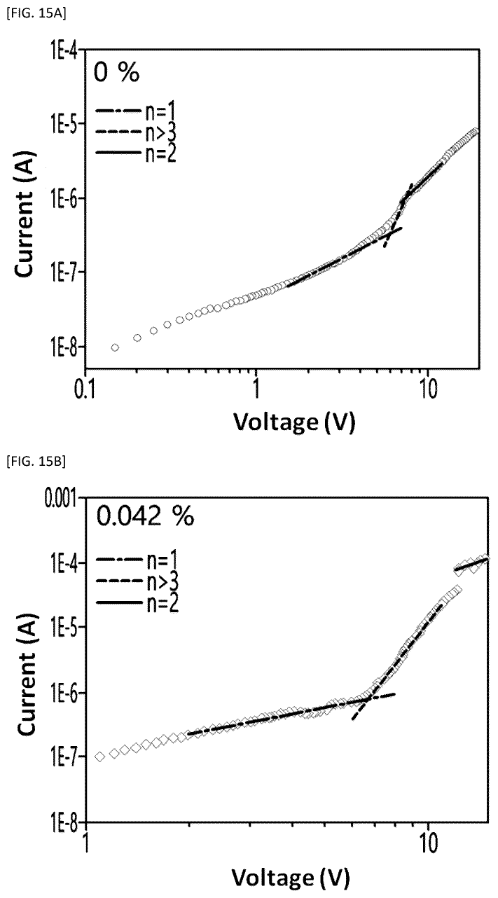

Referring to FIG. 14A, the difference between the single crystal before doping and the single crystal after doping is the presence or absence of Bi peaks in the wide scan. Referring to FIG. 14B to FIG. 14F, peaks corresponding to MAPbBr₃ are observed in binding energy regions of the respective elements. In particular, it can be seen that N 1s, Br 3d, and Pb 4f peaks shift after Bi doping, which implies that the incorporation of Bi affects the bonding strength in the single crystal. In the Bi 4f region, peaks were observed in all single crystal samples except for the undoped one, which confirms the presence of Bi in the doped single crystals. Further, the disappearance of peaks associated with Pb⁰ (metallic Pb) in the Pb 4f region after incorporation of Bi indicates an improvement in stability of the single crystal.

### Dark Current-Voltage (I-V)

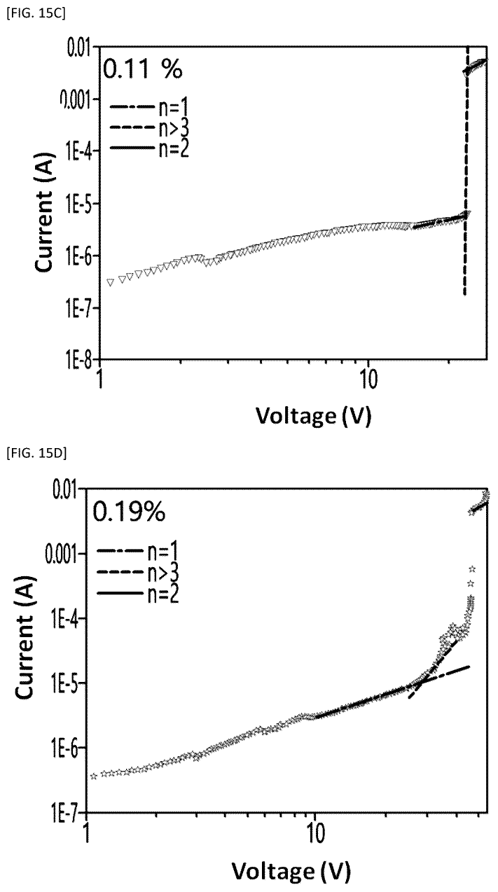

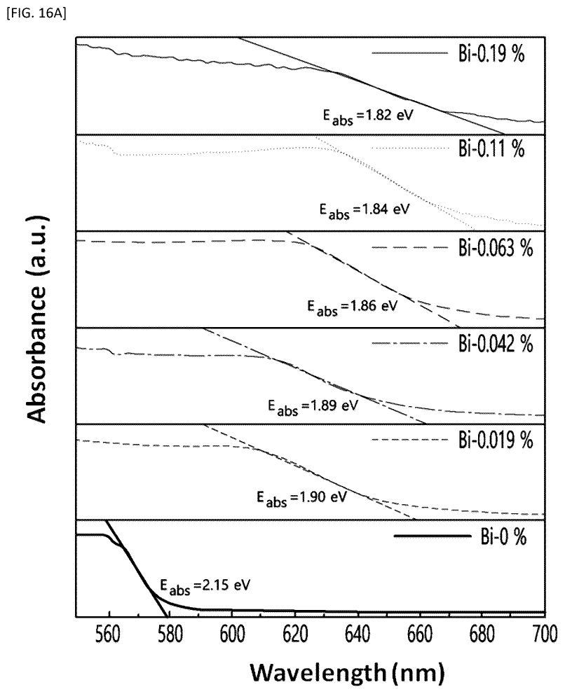

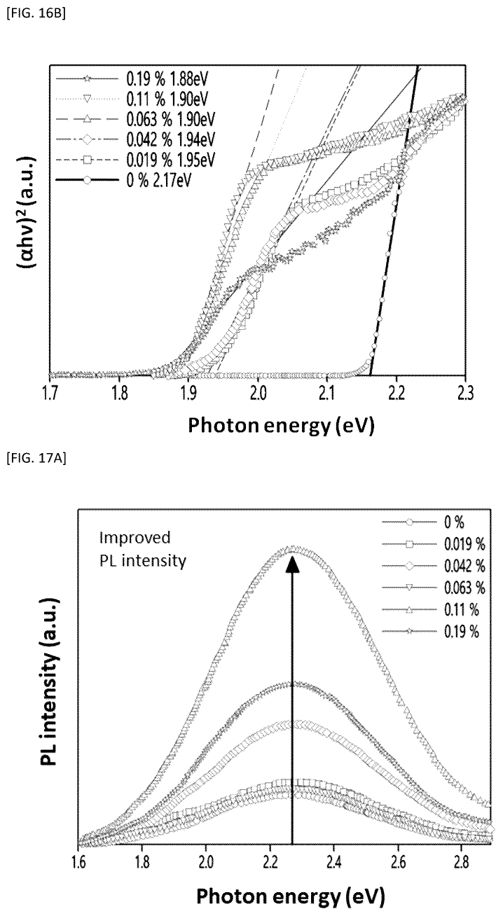

Dark current-voltage (I-V) characteristics were analyzed according to the standard space charge limited current (SCLC) model (FIG. 15A to FIG. 15D). According to Mott-Gurney's law, the I-V curves are divided into three regions: ohmic region (n=1), trap-filled limit region (n>3), and Child's region (n=2), all of which were observed in every single crystal. The carrier mobility and trap density were calculated for each single crystal (Table 4). As the doping concentration increased, both the trap density and the carrier concentration were found to increase. Further, the conductivity calculated in the ohmic region was improved after doping, which confirms the effect of Bi doping. Therefore, it can be seen that electrical characteristics of the single crystal are enhanced through doping.

TABLE 4

| Bi | Conductivity | Trap density | Carrier concentration |
|---|---|---|---|
| Concentration | (Ω⁻¹ cm⁻¹) | (cm⁻³) | (cm⁻³) |
| 0% | 3.86 × 10⁻⁸ | 1.38 × 10¹⁰ | 4.87 × 10⁹ |
| 0.042% | 8.08 × 10⁻⁸ | 7.20 × 10¹¹ | 3.55 × 10¹¹ |
| 0.11% | 1.57 × 10⁻⁷ | 7.62 × 10¹² | 3.53 × 10¹² |
| 0.19% | 3.26 × 10⁻⁷ | 5.85 × 10¹² | 2.75 × 10¹² |

### Optical Absorptance

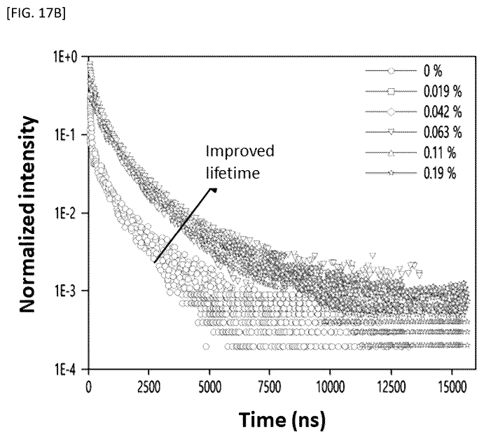

In order to determine whether Bi doping changes the color of the single crystal and consequently alters its light absorption range, UV-Visible spectroscopy was used to measure the optical absorption of the single crystal (FIG. 16A and FIG. 16B). It was confirmed that a wavelength range in which absorption of the single crystal begins increased depending on the doping concentration.

### Photoluminescence (PL)

The photoluminescence was measured under illumination with light of 532 nm wavelength (FIG. 17A). It was confirmed that Bi doping enhanced the photoluminescence intensity of the perovskite. Thus, it was confirmed that Bi doping improved charge transport properties.

Also, the time-dependent photoluminescence was measured under illumination with light of 532 nm wavelength (FIG. 17B and Table 5). It was confirmed that Bi doping increased the carrier lifetime of the perovskite. Thus, it was confirmed that Bi doping improved charge transport properties. Enhanced optical properties may contribute to improved efficiency of perovskite-based optoelectronic devices.

TABLE 5

| | Bi Concentration (%) | | | | | |
|---|---|---|---|---|---|---|
| | 0 | 0.019 | 0.042 | 0.063 | 0.11 | 0.19 |
| τ₁ (ns) | 23.83 | 27.19 | 32.20 | 29.37 | 70.14 | 47.85 |
| A₁ (%) | 92.37 | 74.18 | 70.94 | 72.53 | 62.09 | 65.67 |
| τ₂ (ns) | 422.71 | 660.78 | 679.30 | 657.08 | 779.03 | 716.80 |
| A₂ (%) | 7.63 | 25.82 | 29.06 | 27.47 | 37.91 | 34.33 |
| τ_{average} (ns) | 260.88 | 593.79 | 612.20 | 590.83 | 687.93 | 641.06 |

### Atomic Force Microscopy (AFM)

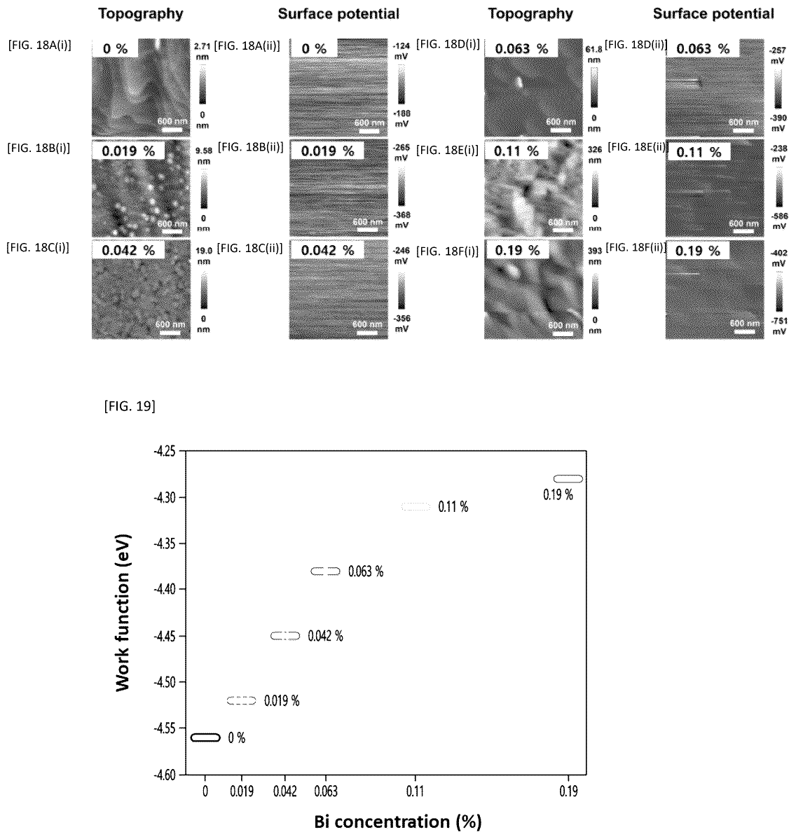

The topography and surface potential of the single crystals were measured by atomic force microscopy (AFM) (FIGS. 18A(i) to 18F(ii)). To confirm whether Bi doping substantially converts the single crystal from p-type to n-type, Kelvin probe force microscopy (KPFM) measurement was conducted. It was confirmed that as the doping concentration increased, a work function of the single crystal decreased 4.57 eV to 4.28 eV (FIG. 19). The decrease in work function indicates that the p-type single crystal was doped to become n-type single crystal.

The above description of the present disclosure is provided for the purpose of illustration, and it would be understood by those skilled in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A method of preparing a doped perovskite single crystal, comprising:
dissolving compounds represented by the following Chemical Formulas 1, 2 and 3 in a solvent to prepare a precursor solution; and
heating the precursor solution to grow a perovskite single crystal,
wherein a molar ratio of the compounds represented by the Chemical Formulas 1, 2 and 3 is 1:1-n:n, and
wherein the doped perovskite single crystal is a compound represented by the following Chemical Formula 4:
AX; [Chemical Formula 1]
M¹X₂; [Chemical Formula 2]
M²X or M²X₃; [Chemical Formula 3]
A(M¹₁₋ₘM²ₘ)X₃; [Chemical Formula 4]
wherein, in the Chemical Formulas 1 to 4,
A includes at least one selected from organic ammonium, organic amidinium, Cs, Rb, and K,
M¹ includes at least one divalent metal cation(s) selected from Pb, Cu, Ni, Co, Fe, Mn, Cr, Pd, Cd, Ca, Yb, Sn, Ge, Sr, Mg, Zn, and Eu,
M² represents a dopant and includes at least one selected from a monovalent metal cation including Ag, Cu, Na, Li, or Ti and a trivalent metal cation including Bi, Sb, In, Au, Yb, Y, Ho, Er, Nd, Pr, Dy, La, or Eu,
X includes at least one selected from Cl, Br, and I and is the same as or different from each other in the Chemical Formulas 1 to 4, and
m represents a doping concentration of the dopant and is more than 0 to 0.2 or less.

2. The method of claim 1,
wherein, in the Chemical Formulas 1 to 4,
A includes at least one selected from alkylammonium containing an alkyl group having 1 to 15 carbon atoms, methylenediammonium, dimethylammonium, phenethylammonium, 4-fluoro-phenethylammonium, pyrene-ammonium, pyrene-methylammonium, pyrene-ethylammonium, formamidinium, acetamidinium, guanidinium, Cs, Rb, and K.

3. The method of claim 1,
wherein n is more than 0 to 0.5 or less.

4. The method of claim 1,
wherein m increases in proportion to n.

5. The method of claim 1,
wherein a molar concentration of the precursor solution is 0.5 M to 3 M.

6. The method of claim 1,
wherein the doped perovskite single crystal is MAPbBr₃ or MAPbI₃ doped by the dopant.

7. The method of claim 1,
wherein, when the precursor solution is heated, a heating rate varies depending on a temperature range.

8. The method of claim 7,
wherein, when the perovskite is MAPbBr₃,
the heating rate is 0.2° C./min to 0.3° C./min in a temperature range of 20° C. to 60° C., 0.1° C./min to 0.2° C./min in a temperature range of 60° C. to 100° C., 0.01° C./min to 0.1° C./min in a temperature range of 100° C. to 130° C., and 0.01° C./min to 0.1° C./min in a temperature range of 130° C. to 150° C.

9. The method of claim 7,
wherein, when the perovskite is MAPbI₃,
the heating rate is 0.01° C./min to 0.1° C./min in a temperature range of 80° C. to 110° C., 0.01° C./min to 0.1° C./min in a temperature range of 110° C. to 140° C., and 0.01° C./min to 0.1° C./min in a temperature range of 140° C. to 170° C.

10. The method of claim 1,
wherein the precursor solution further includes formic acid.

11. A doped perovskite single crystal prepared by the method according to claim 1,
wherein the doped perovskite single crystal is represented by the following Chemical Formula 4:
A(M¹₁₋ₘM²ₘ)X₃; [Chemical Formula 4]
wherein, in the Chemical Formulas 1 to 4,
A includes at least one selected from organic ammonium, organic amidinium, Cs, Rb, and K,
M¹ includes at least one divalent metal cation(s) selected from Pb, Cu, Ni, Co, Fe, Mn, Cr, Pd, Cd, Ca, Yb, Sn, Ge, Sr, Mg, Zn, and Eu,
M² represents a dopant and includes at least one selected from a monovalent metal cation including Ag, Cu, Na, Li, or Ti and a trivalent metal cation including Bi, Sb, In, Au, Yb, Y, Ho, Er, Nd, Pr, Dy, La, or Eu,
X includes at least one selected from Cl, Br, and I and is the same as or different from each other in the Chemical Formulas 1 to 4, and
m represents a doping concentration of the dopant and is more than 0 to 0.2 or less.

12. The doped perovskite single crystal of claim 11,
wherein a full width at half maximum (FWHM) of XRD peak of the doped perovskite single crystal is 0.07 or less.

13. The doped perovskite single crystal of claim 11,
wherein a conductivity of the doped perovskite single crystal is 8×10⁻⁸ Ω⁻¹cm⁻¹ or more.

14. The doped perovskite single crystal of claim 11,
wherein a carrier lifetime of the doped perovskite single crystal is 500 ns or more.
